(19) United States
(12) Patent Application Publication
(10) Pub. No.: US 2026/0013047 A1
(43) Pub. Date: Jan. 8, 2026

(54) CIRCUIT BOARD AND ELECTRONIC DEVICE INCLUDING THE SAME

(71) Applicant: LG ELECTRONICS INC., Seoul (KR)

(72) Inventor: Kyungsup OH, Seoul (KR)

(73) Assignee: LG ELECTRONICS INC., Seoul (KR)

(21) Appl. No.: 19/041,550

(22) Filed: Jan. 30, 2025

(30) Foreign Application Priority Data
Jul. 4, 2024 (WO) PCT/KR2024/009446

(51) Int. Cl. H05K 1/18; H01G 4/30; H05K 7/14

(52) U.S. Cl. CPC H05K 1/181; H01G 4/30; H05K 7/1427; H05K 2201/10015

(57) ABSTRACT

A circuit board including a first pattern, a second pattern located adjacent to the first pattern, a narrow pattern extended from the second pattern, a first electrode overlapping the first pattern, a second electrode connected to an end of the narrow pattern, and a multilayer ceramic capacitor (MLCC) configured to electrically connect the first pattern and the second pattern by being connected to the first electrode and the second electrode protects an electronic device by not causing ignition even if a crack occurs in the MLCC.

### CROSS-REFERENCE TO RELATED APPLICATIONS

This application claims the benefit of PCT Patent Application No. PCT/KR2024/009446, filed on Jul. 4, 2024, which is hereby incorporated by reference as if fully set forth herein.

### TECHNICAL FIELD

The present disclosure relates to a circuit board having a high-frequency generating electronic component, such as a multilayer ceramic capacitor, mounted thereon, and an electronic device including the same.

### BACKGROUND

Typically, various types of electronic devices equipped with a central processing unit (CPU) and a direct current (DC)/DC converter have numerous multilayer ceramic capacitors mounted on a printed circuit board (PCB).

A multilayer ceramic capacitor (MLCC) is a component that is made by stacking multiple layers of ceramic and metal and heating the layers at high temperature to control a constant flow of current in an electronic product circuit. The MLCC is a required component because there is a risk of component damage when current flowing into a circuit is uneven.

As electronic devices such as smartphones and tablets proliferate, the demand for MLCCs has increased, and the demand for automotive electronic components has increased rapidly recently.

MLCCs with more layers are capable of storing a lot of electricity, and thus the key is to increase the number of layers while making a product size as small as possible. However, as the product size is reduced, the product becomes more vulnerable to external impact and cracks may occur.

When a crack occurs in an MLCC, insulation is destroyed, a short circuit occurs between two electrodes, and the MLCC catches fire, damaging other parts of a circuit board.

### SUMMARY

The present disclosure provides an electronic device for preventing damage to an entire circuit board due to ignition caused by cracks in a multilayer ceramic capacitor (MLCC).

A circuit board includes a first pattern, a second pattern located adjacent to the first pattern, a narrow pattern extended from the second pattern, a first electrode overlapping the first pattern, a second electrode connected to an end of the narrow pattern, and an MLCC configured to electrically connect the first pattern and the second pattern by being connected to the first electrode and the second electrode.

Resistance of the narrow pattern may have a value less than or equal to 50% of resistance of the MLCC.

In an total reactance X value of the narrow pattern and the MLCC has a value of 85% or more of a reactance value of the MLCC.

The narrow pattern may have a length of more than 0.75 mm and less than 1.25 mm.

The narrow pattern may have a width of 0.125 mm or less.

A cross section perpendicular to a longitudinal direction of the narrow pattern may have an area of 4.375×10⁻³ mm² or less.

The second pattern may be ground.

The second pattern may include a recessed portion that is concavely formed in a C-shape surrounding three sides of the second electrode and has a first side extending from the narrow pattern, the first side may have a gap corresponding to a length of the second electrode and the narrow pattern, and a second side and a third side of the recessed portion may be spaced apart from the second electrode by a gap of 0.3 mm or more.

The first pattern may be located between a power supply and a DCDC converter.

The circuit board may further include a power supply configured to supply power to the first pattern and switch to a hiccup mode that periodically turns on and off power based on overcurrent being detected, wherein the narrow pattern may be broken within one cycle of the hiccup mode.

The MLCC may have a capacitance of 10 uF or less.

### BRIEF DESCRIPTION OF THE DRAWINGS

FIG. 1 is a diagram showing a circuit board on which a multilayer ceramic capacitor (MLCC) is mounted.

FIG. 2 is a partial cutaway perspective view illustrating an MLCC.

FIG. 3 is a cross-sectional view of an MLCC.

FIG. 4 is a diagram showing a flow of current when an MLCC of a conventional electronic device.

FIG. 5 is a diagram showing a flow of current when an MLCC 185 of an electronic device according to the present disclosure is damaged.

FIG. 6 is a conceptual diagram for explaining a configuration of an electronic device according to the present disclosure.

FIG. 7 is a table showing a pattern width at which a narrow pattern of an electronic device according to the present disclosure is broken.

FIG. 8 is a diagram showing an equivalent circuit of an MLCC according to the resistance and inductance based on the size of a narrow pattern of an electronic device and addition of the narrow pattern, according to the present disclosure.

FIG. 9 is a table showing a change rate of reactance of an MLCC according to the resistance and inductance based on the size of a narrow pattern of an electronic device and addition of the narrow pattern, according to the present disclosure.

FIG. 10 is a table showing the amount of reactance reduction according to presence or absence of a narrow pattern and the capacitance of an MLCC.

FIG. 11 is a graph showing a hiccup mode that occurs when an MLCC is broken and a temperature change of the MLCC.

FIG. 12 is a table showing occurrence of ignition and hiccup current in an MLCC according to the specifications of a narrow pattern.

FIG. 13 is a diagram showing the arrangement of a narrow pattern and a second pattern of an electronic device according to the present disclosure.

### DETAILED DESCRIPTION

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

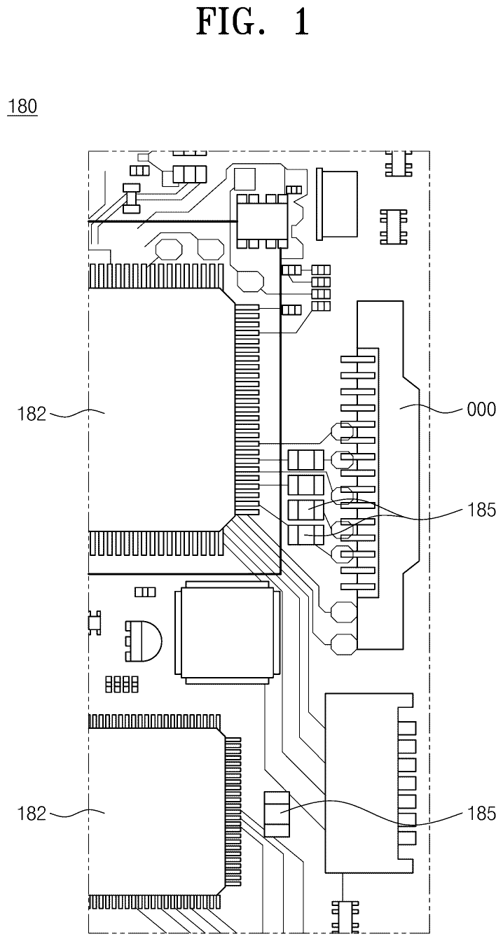

FIG. 1 is a diagram showing a circuit board 180 on which a multilayer ceramic capacitor (MLCC) 185 is mounted. An electronic device may include a plurality of electronic modules having special functions and include the circuit board 180 that transmits and receives signals to control each electronic module. The circuit board 180 includes a conductive strip-shaped wiring 184 conductor on an insulating material by printing technology, plating technology, etching technology, or the like. Electronic components such as a plurality of integrated circuits 182 and a connector 183 for connection to other electronic modules may be fixed to a surface of the circuit board 180 and connected between the electronic components through the wiring 184.

The MLCC may be placed at connection between electronic components of a printed circuit board. The MLCC 185 stably controls a flow of electricity within an electronic product and prevents electromagnetic interference between components. The MLCC 185 is a required component in an electronic device because the MLCC 185 removes noise included in current and prolongs the lifetime of an electronic product.

More than 800 MLCCs 185 are mounted in a smartphone, and products such as LED TVs require 2,000 MLCCs 185.

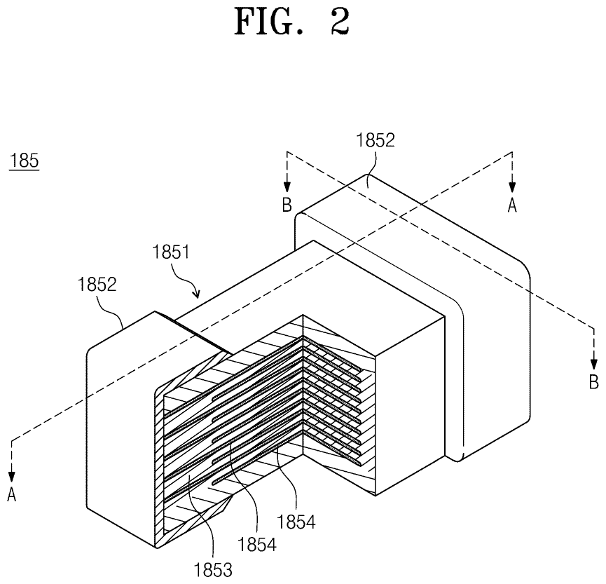

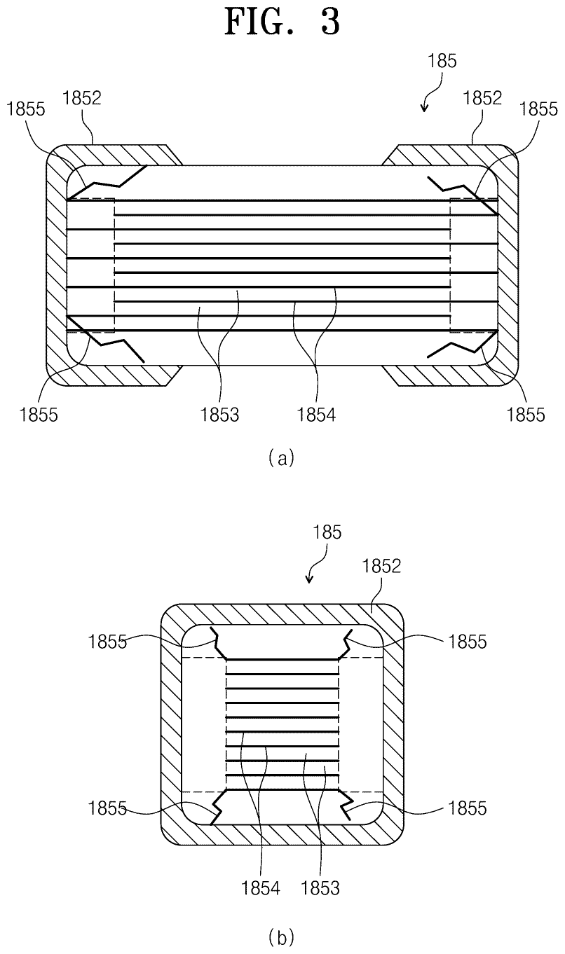

FIG. 2 is a partial cutaway perspective view illustrating the MLCC 185, and FIG. 3 is a cross-sectional view of the MLCC 185.

The MLCC 185 may include a multilayer portion 1851 in which an electrode layer 1854 including multiple layers of metal materials and a ceramic layer 1853 are stacked, and an external electrode 1852 for connecting to the wiring 184 at both ends of the multilayer portion 1851.

The MLCC 185 may store electricity between a plurality of electrode layers 1854, and thus, as the number of layers increases, the amount of the stored electricity may increase. The MLCC 185 may be a large-capacity capacitor and may control a flow of current between the wirings 184. The capacity of the MLCC 185 may vary depending on the number and size of the stacked electrode layers 1854. The MLCC 185 widely used in display devices mainly has 10 uF and 4.7 uF.

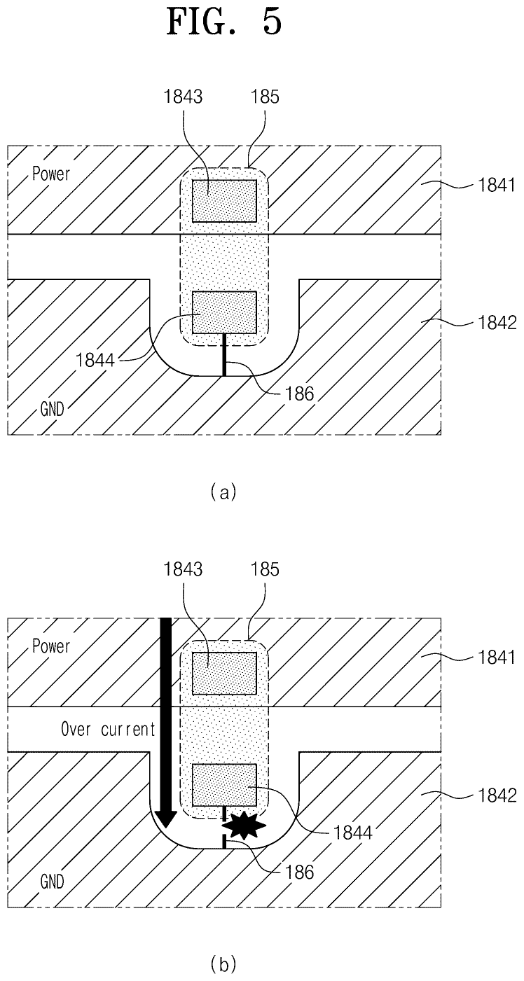

The MLCC 185 may perform a rectifying function to smooth a flow of electricity within a device and may remove noise, which is an unnecessary interference phenomenon. However, the MLCC 185 includes thin ceramic, and thus, cracks 1855 may easily occur as shown in FIG. 3. In the MLCC 185, a pair of electrodes 1843 and 1844 (refer to FIG. 5) exposed on the circuit board 180 and the external electrode 1852 may be soldered together and electrically connected to each other.

When the circuit board 180 is bent or subjected to external impact, the cracks 1855 may occur in the ceramic layer 1853 of the multilayer portion 1851. When the cracks 1855 occurs in the ceramic layer 1853, insulation between the electrode layers 1854 may be destroyed, causing a short circuit between the electrode layers 1854.

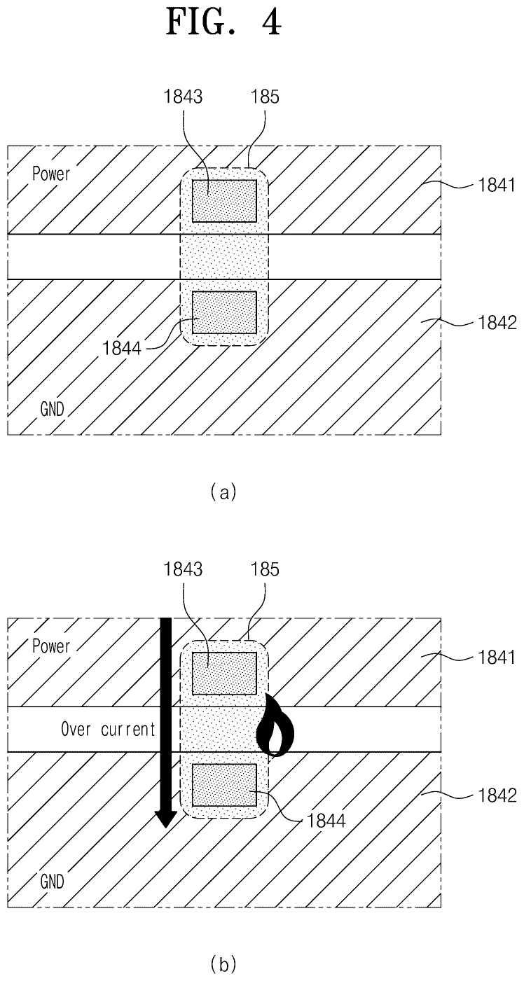

FIG. 4 is a diagram illustrating the MLCC 185 of a conventional electronic device. As shown in (a), the MLCC 185 may be located between a first pattern 1841 and a second pattern 1842. A first electrode 1843 connected to the first pattern 1841 and a second electrode 1844 connected to the second pattern 1842 may be exposed on a surface of the circuit board 180.

The first electrode 1843 and the second electrode 1844 may be arranged to overlap the first pattern 1841 and the second pattern 1842 as shown in FIG. 4. That is, the first electrode 1843 and the second electrode 1844 may be implemented in a form in which a part of the first pattern 1841 and the second pattern 1842 are exposed on the surface of the circuit board 180.

The first pattern 1841 may be connected to a power supply. The MLCC 185 may be added to the first pattern 1841 such that power supplied from the power supply may be stably supplied to each component. The MLCC 185 may connect the first pattern 1841 to a ground, and the second pattern 1842 connected to the second electrode 1844 described above may be the ground.

When a crack occurs in the MLCC 185, the temperature inside the MLCC 185 may rise and ignite, causing a fire. Even if it does not lead to a fire, the ignition of the MLCC 185 may cause carbonization of an epoxy component of the circuit board 180, and overcurrent may occur between the power supply and the ground, which may damage electronic components or cause a fire.

The first pattern 1841, which is a power pattern, may have a thickness of 35 μm and use a 5 mm wide wiring, and according to the IPC-2221 standard, the maximum allowable current of the 5 mm wide wiring may be 9.1 A. Therefore, when more current flows than this, the wiring may be damaged. When the first pattern 1841 has a thick width, the first pattern 1841 may be prevented from being damaged at high current, but there is a problem that the size of the circuit board 180 increases, making it difficult to realistically apply a wide power pattern.

Therefore, to minimize impact on other components on the circuit board 180 when a crack occurs in the MLCC 185, it is necessary to block a flow passing through the MLCC 185 before damage to the first pattern 1841 and ignition of the MLCC 185.

Accordingly, the present disclosure further includes a narrow pattern 186 to block current passing through the MLCC 185 before ignition when overcurrent flows due to cracking of the MLCC 185.

FIG. 5 is a diagram showing a flow of current when the MLCC 185 of an electronic device according to the present disclosure is damaged. The electronic device according to the present disclosure includes the first pattern 1841, the second pattern 1842, the first electrode 1843 connected to the first pattern 1841, the narrow pattern 186 extended from the second pattern 1842, and the second electrode 1844 connected to the narrow pattern 186, and the MLCC 185 is connected to the first electrode 1843 and the second electrode 1844.

Unlike FIG. 4, the second electrode 1844 may not be directly connected to the second pattern 1842 but may be connected through the narrow pattern 186.

The narrow pattern 186 may have a width thinner than the width of the second electrode 1844 and may have a predetermined length. The narrow pattern 186 may be disconnected to prevent ignition of the MLCC 185 when overcurrent flows.

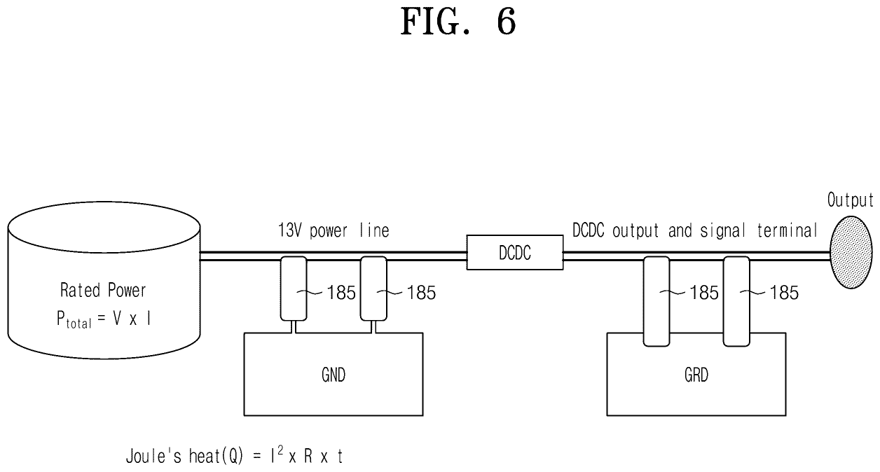

FIG. 6 is a conceptual diagram for explaining a circuit configuration of an electronic device according to the present disclosure. As illustrated in FIG. 6, power supplied from the power supply is supplied to a DCDC converter 187 through the first pattern 1841, and the DCDC converter 187 drops a voltage to allow a low current to flow in a section after output of the DCDC converter, in which the power is supplied to each electronic component. The DCDC converter 187 itself has an over voltage protection (OCP) function in its IC, and thus damage to the MLCC 185 after the DCDC does not occur.

Therefore, the narrow pattern 186 of the electronic device according to the present disclosure may be applied to an MLCC, which connects the first pattern, for connecting the power supply and the DCDC converter 187, and the second pattern 1842 (ground).

It is necessary to design a pattern width by which the narrow pattern 186 is broken before ignition of the MLCC 185. A melting point of copper is 1,085° C., a boiling point of copper is 2,562° C., and an ignition temperature of the MLCC 185 is about 1, 300° C.

It may be possible to design the narrow pattern 186 in which the temperature of the narrow pattern 186 becomes 2,562° C. or higher before the temperature of the MLCC 185 reaches 1,300° C.

Joule heat (Q) may be calculated as the product of a square of current and the resistance and time, and when the MLCC 185 cracks, as the resistance and current of the narrow pattern 186 increases, the narrow pattern 186 may be broken fast.

$$Q = {I}^{2} \times R \times t \qquad [ Equation 1 ]$$

Resistance may be inversely proportional to the width of the narrow pattern 186, and the width of the narrow pattern 186 may be determined according to the rated current of the electronic device. When the rated current of the electronic device flows, the temperature of the narrow pattern 186 needs to rise to the boiling point of copper at which the narrow pattern 186 is to be broken.

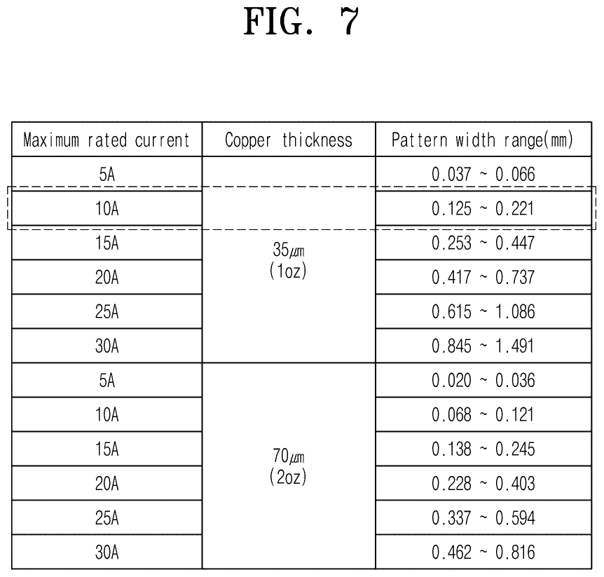

FIG. 7 is a table showing a pattern width at which the narrow pattern 186 of the electronic device according to the present disclosure is broken. The table shows a range of the width of the narrow pattern 186 that is broken at 2,552° C. according to the maximum rated current.

As the rated current increases, the narrow pattern 186 may increase, and the explanation will be based on an electronic device with a rated current of 10 A. When the thickness of a copper foil is 35 μm and a pattern width has a value of 0.125 to 0.221 mm, the narrow pattern 186 is broken when a current of 10 A flows. When the thickness of the copper foil is doubled to 70 μm, the pattern width needs to be reduced by about half.

The circuit board 180 including the 35 μm copper foil is generally used, and thus the following description is based on the 35 μm copper foil. Therefore, the narrow pattern 186 of 0.125 mm or less may be understood to have the same meaning as the narrow pattern 186 with a cross-sectional area of 4.375×10⁻³ mm².

The narrow pattern 186 having a width of 0.1 mm may be designed such that the narrow pattern 186 may be broken before reaching the rated current. As described above, the width of the narrow pattern 186 may vary depending on the rated current and the thickness of the copper foil.

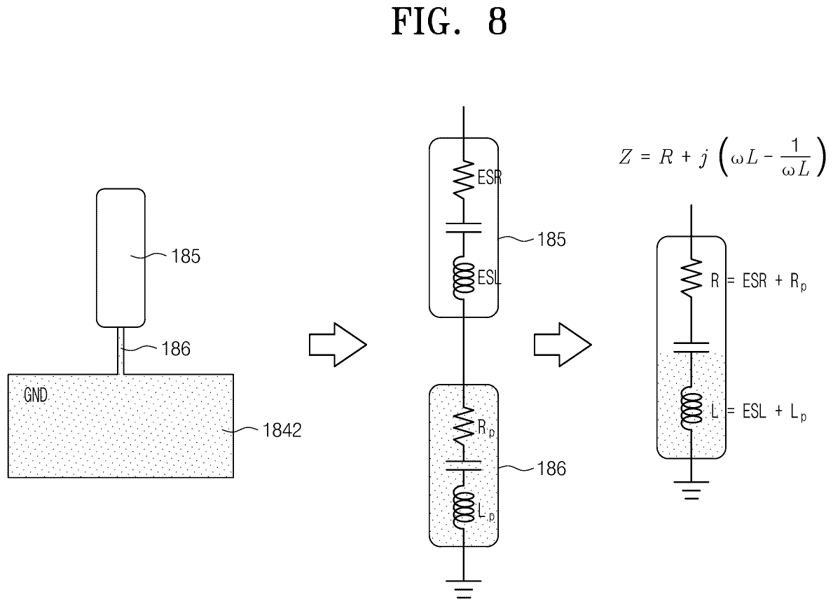

FIG. 8 is a diagram showing an equivalent circuit of the MLCC 185 according to the resistance and inductance based on the size of the narrow pattern 186 of the electronic device and addition of the narrow pattern 186, according to the present disclosure.

When illustrated in a circuit diagram, the MLCC 185 may have not only a capacitor value but also resistance ESR and inductance ESL components. Inductance reactance XL is ωL (ω is an angular frequency of 2 πf), and a value thereof increases as a frequency increases. The inductance component of the MLCC 185 is very small, and thus an inductance reactance value of 1 nH or more may be obtained at a high frequency of 3 to 4 MHz or more.

The MLCC 185 according to the present disclosure may operate in a frequency band of 1 NMHz or less, and thus the inductance component of the MLCC 185 may not affect the overall circuit configuration.

When the narrow pattern 186 is connected to the MLCC 185, the resistance and inductance components of the narrow pattern 186 affect an impedance value of the MLCC 185. The resistance of the narrow pattern 186 may be called parasitic resistance, and the inductance of the narrow pattern 186 may be called parasitic inductance. The sum of the resistance and parasitic resistance of the MLCC 185 may be integrated resistance of the MLCC 185 to which the narrow pattern 186 is added, and the sum of the inductance and parasitic inductance Lp of the MLCC 185 may be integrated inductance.

Integrated impedance Z of the narrow pattern 186 in the MLCC 185 may be derived through the following value.

$$Z = R + j ( ω L - \frac{1}{ω C} ) \qquad [ Equation 2 ]$$

$$R = ESR + Rp , L = ESL + Lp Lp C = capacitance of MLCC$$

When the overall resistance changes significantly due to addition of parasitic resistance, the overall impedance changes, and thus the size of the parasitic resistance may be smaller than the resistance ESR of the MLCC 185. The size of the parasitic resistance may have a value equal to or less than 50%.

The reactance of the MLCC 185 is very small, and thus the integrated reactance L is practically equal to the parasitic reactance value Lp. As the parasitic reactance Lp is added, an inductive reactance value (XL=ωL) reactance value is generated, which causes a decrease in the capacitive reactance value Xc of the MLCC 185, thereby reducing the integrated reactance (X=ωL−1/(ωC)).

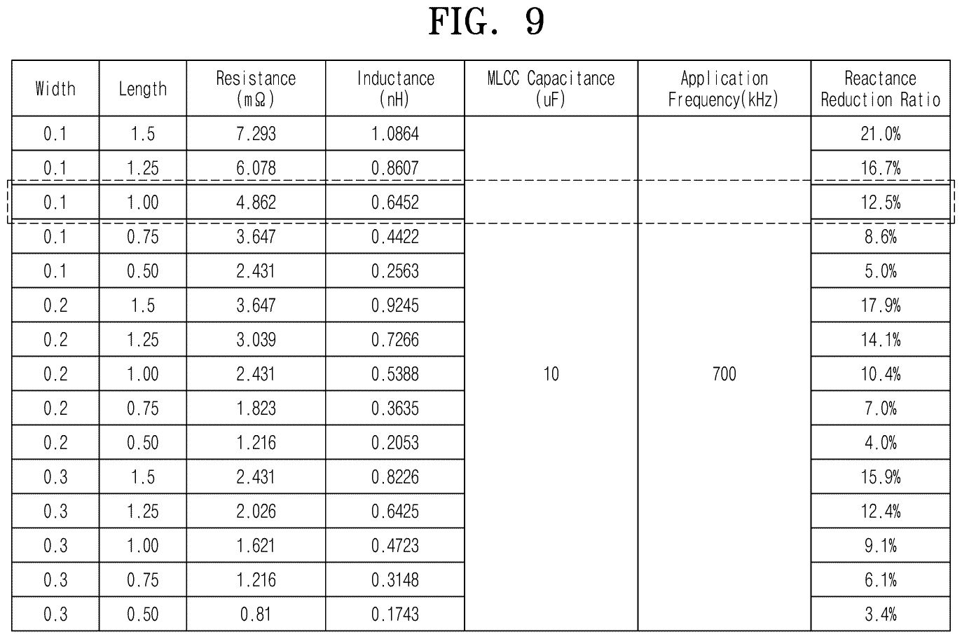

FIG. 9 is a table showing a change rate of reactance of the MLCC 185 according to the resistance and inductance based on the size of the narrow pattern 186 of the electronic device and addition of the narrow pattern 186, according to the present disclosure.

When a rate of reduction in reactance X is large due to addition of the parasitic inductance Lp value of the narrow pattern 186 added to the MLCC 185 having a capacity of 10 uF at a frequency of 700 kHz, the performance of the MLCC 185 may be affected in normal operation. Accordingly, the length of the narrow pattern 186 may be determined such that a rate of reduction X 15% or less.

1.25 mm shows a reduction rate of 16%, and thus the length of the narrow pattern 185 may have a length less than 1.25 mm.

As seen from FIG. 7, the narrow pattern 186 with a width of 0.1 mm has a small reduction rate of reactance due to parasitic inductance Lp when the narrow pattern 186 has a length of 1 mm or less, and the size of the resistance is also reduced as the length of the narrow pattern 186 is reduced, and thus the size of the parasitic resistance may also have a small value.

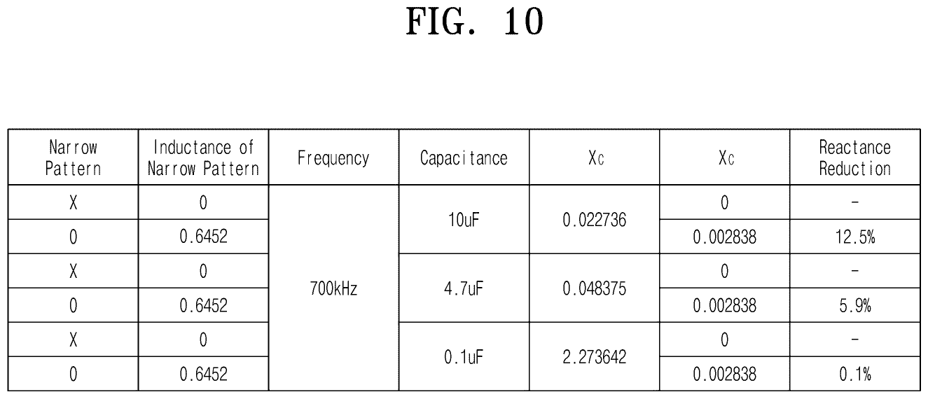

FIG. 10 is a table showing the amount of reactance reduction according to presence or absence of the narrow pattern 186 and the capacitance of the MLCC 185.

The amount of reactance reduction according to the capacitance of the MLCC 185 is shown depending on whether the narrow pattern 186 with a width of 0.1 mm and a length of 1 mm is added. The table in FIG. 9 shows the capacitive reactance Xc of 0.22736 as a value for the MLCC 185 of 10 uF and a reduction ratio of 12.5% by reducing reactance by inductive reactance Xl due to addition of the narrow pattern 186.

When the capacitance is small, capacitive reactance Xc is relatively larger, and thus the amount of reactance reduction may be reduced, and the performance of the MLCC 185 may be maintained. Accordingly, the narrow pattern 186 with a width of 0.1 mm and a length of 1 mm may added to the MLCC 185 of a different capacitance.

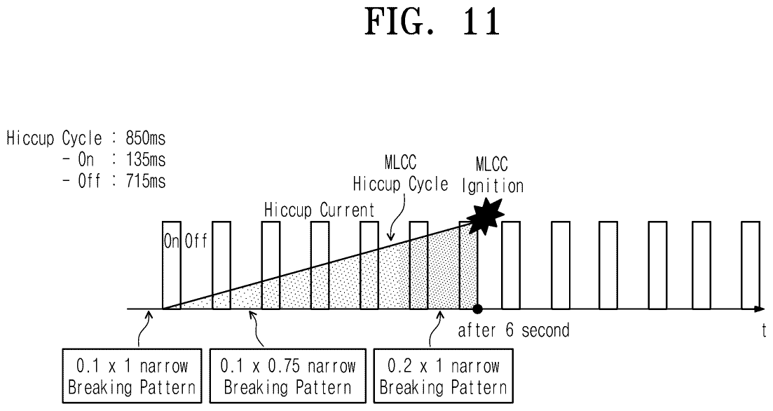

FIG. 11 is a graph showing a hiccup mode that occurs when an MLCC is broken and a temperature change of the MLCC 185. When the resistance is small, the impact on the performance of the MLCC 185 is small, but it may take more time for the narrow pattern 186 to be short-circuited. As seen in Equation 1, as a value R decreases, a value t needs to relatively increase.

When the narrow pattern 186 is added, the MLCC 185 may be short-circuited before ignition, but smoke may be generated in the MLCC 185 due to the hiccup mode. The hiccup mode is a form of overcurrent protection in a power supply, which means that when overcurrent is detected, the power supply cycles power off and on repeatedly. When power is applied in hiccup mode, overcurrent may pass through the MLCC 185, the internal temperature may rise, and smoke may be generated accordingly.

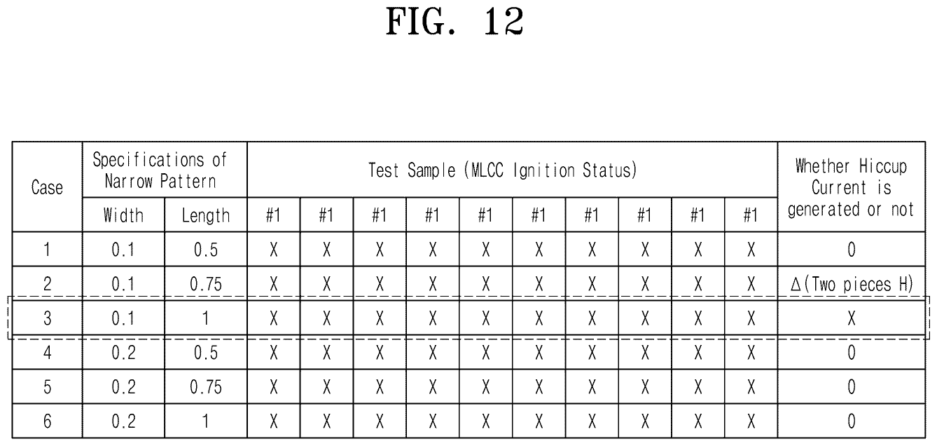

The narrow pattern 186 is short-circuited before the MLCC 185 reaches an ignition temperature, but a short-circuiting time may vary depending on the width and length of the narrow pattern 186. FIG. 12 is a table showing occurrence of ignition and hiccup current of an MLCC according to the specifications of the narrow pattern 186 added to the MLCC 185 of 10 uF.

A hiccup cycle of the power supply of the present embodiment supplies power in a cycle of 850 ms with On 135 ms and Off 715 ms. Tests are conducted on narrow patterns 186 having specifications with a smaller resistance value than those having a width of 0.1 mm and a length of 1 mm. Except for a narrow pattern with a width of 0.1 mm and a length of 1 mm, it may be seen that no short circuit occurs before the hiccup current is generated.

That is, smoke may occur several times due to hiccup current before the current is interrupted due to a short circuit. To avoid smoke generation due to hiccup current, the length of the narrow pattern 186 needs to be set such that the narrow pattern 186 is short-circuited before the hiccup current is generated.

Therefore, when the narrow pattern 186 has a width of 0.1 mm and a length of 1 mm, the narrow pattern 186 may be short-circuited before the hiccup current is generated while minimizing the impact on the performance of the MLCC 185.

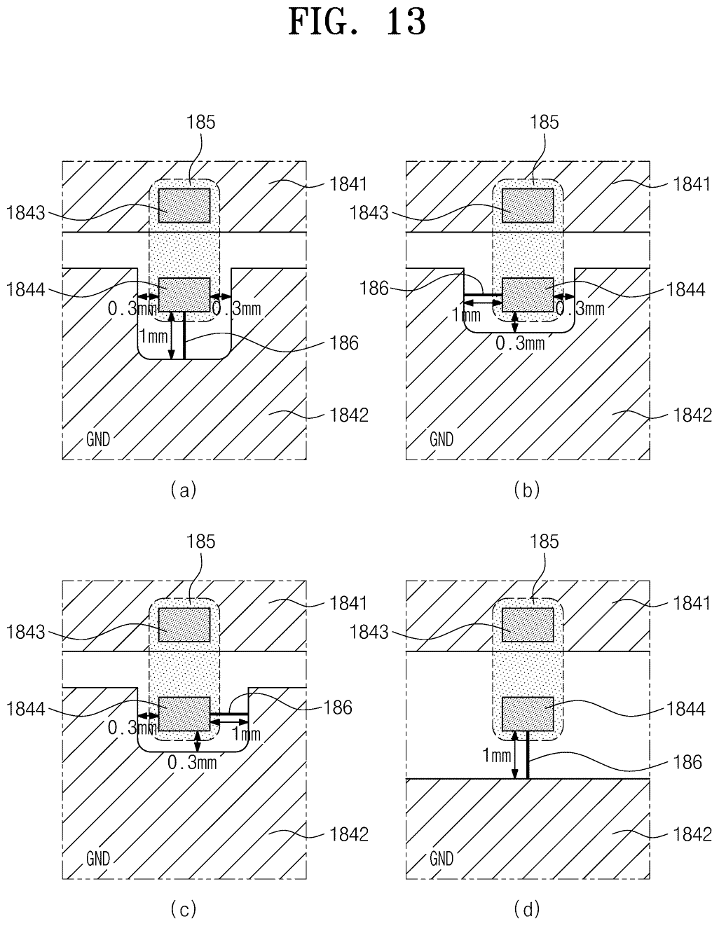

FIG. 13 is a diagram showing the arrangement of the narrow pattern 186 and the second pattern 1842 of an electronic device according to the present disclosure. The narrow pattern according to the present disclosure may have a length of 1 mm, and thus to implement the narrow pattern by changing a design in the existing circuit diagram, a shape of the second pattern 1842 (ground) may be configured as a concave shape as shown in FIG. 13 to be spaced apart from the second electrode 1844 by a predetermined distance.

The second pattern 1842 may be connected to the narrow pattern 186 at one side of the second electrode 1844. A connection direction of the narrow pattern 186 may be any direction regardless of the arrangement of the MLCC 185, and a portion in which the narrow pattern 186 is not connected may be configured such that a gap between the second electrode 1844 and the second pattern 1842 is 0.3 mm or more.

When designing a new circuit diagram, the second pattern 1842 may also be configured in a form that does not surround the second electrode 1844, as in (d) of FIG. 13.

As described above, the electronic device according to the present disclosure may protect the electronic device by not causing ignition even if a crack occurs in the MLCC 185.

The electronic device according to the present disclosure may resolve a failure through partial repair by preventing damage to the entire circuit board 180.

The electronic device according to the present disclosure may maintain a function of the MLCC 185 even if the narrow pattern 186 is added.

The above detailed description should not be construed as being limitative in all terms, but should be considered as being illustrative. The scope of the present disclosure should be determined by reasonable analysis of the accompanying claims, and all changes in the equivalent range of the present disclosure are included in the scope of the present disclosure.

As for the various embodiments for implementing the present disclosure, redundant descriptions are omitted as they have been described above in Best Mode of the present disclosure.

The present disclosure may be applied to circuit boards and electronic devices in various fields, and thus the industrial applicability thereof is obtained.

An electronic device according to the present disclosure may be protected by not causing ignition even if a crack occurs in a multilayer ceramic capacitor (MLCC).

The electronic device according to the present disclosure may resolve a failure through partial repair by preventing damage to an entire circuit board.

The electronic device according to the present disclosure may maintain a function of an MLCC even if a narrow pattern is added.

Effects obtainable from the present disclosure are not limited by the above mentioned effects, and other unmentioned effects can be clearly understood from the above description by those having ordinary skill in the technical field to which the present disclosure pertains.

What is claimed is:

1. A circuit board comprising:
a first pattern;
a second pattern located adjacent to the first pattern;
a narrow pattern extended from the second pattern;
a first electrode overlapping the first pattern;
a second electrode connected to an end of the narrow pattern; and
a multilayer ceramic capacitor (MLCC) configured to electrically connect the first pattern and the second pattern by being connected to the first electrode and the second electrode.

2. The circuit board of claim 1, wherein resistance of the narrow pattern has a value less than or equal to 50% of resistance of the MLCC.

3. The circuit board of claim 1, wherein an total reactance X value of the narrow pattern and the MLCC has a value of 85% or more of a reactance value of the MLCC.

4. The circuit board of claim 1, wherein the narrow pattern has a length of more than 0.75 mm and less than 1.25 mm.

5. The circuit board of claim 1, wherein the narrow pattern has a width of 0.125 mm or less.

6. The circuit board of claim 1, wherein a cross section perpendicular to a longitudinal direction of the narrow pattern has an area of 4.375×10⁻³ mm² or less.

7. The circuit board of claim 1, wherein the second pattern is ground.

8. The circuit board of claim 1, wherein the second pattern includes a recessed portion that is concavely formed in a C-shape surrounding three sides of the second electrode and has a first side connecting with the narrow pattern, and
wherein a gap between the second electrode and the first side of the recess portion corresponds to a length of the narrow pattern.

9. The circuit board of claim 1, wherein the recessed portion has a second side and a third side spaced apart from the second electrode by a gap of 0.3 mm or more.

10. The circuit board of claim 1, wherein the first pattern is located between a power supply and a DCDC converter.

11. The circuit board of claim 1, further comprising a power supply configured to supply power to the first pattern and switch to a hiccup mode that periodically turns on and off power based on overcurrent being detected,
wherein the narrow pattern is broken within one cycle of the hiccup mode.

12. The circuit board of claim 1, wherein the MLCC has a capacitance of 10 uF or less.

13. An electronic device comprising:
a housing; and
a circuit board installed inside of the housing,
wherein the circuit board includes:
a first pattern;
a second pattern located adjacent to the first pattern;
a narrow pattern extended from the second pattern;
a first electrode overlapping the first pattern;
a second electrode connected to an end of the narrow pattern; and
a multilayer ceramic capacitor (MLCC) configured to electrically connect the first pattern and the second pattern by being connected to the first electrode and the second electrode.

14. The electronic device of claim 13, wherein resistance of the narrow pattern has a value less than or equal to 50% of resistance of the MLCC.

15. The electronic device of claim 13, wherein an total reactance X value of the narrow pattern and the MLCC has a value of 85% or more of a reactance value of the MLCC.

16. The electronic device of claim 13, wherein the narrow pattern has a length of more than 0.75 mm and less than 1.25 mm, and a width of 0.125 mm or less.

17. The electronic device of claim 13, wherein the second pattern includes a recessed portion that is concavely formed in a C-shape surrounding three sides of the second electrode and has a first side connecting with the narrow pattern,
wherein a gap between the second electrode and the first side of the recess portion corresponds to a length of the narrow pattern, and
wherein the recessed portion has a second side and a third side spaced apart from the second electrode by a gap of 0.3 mm or more.

18. The electronic device of claim 13, wherein the first pattern is located between a power supply and a DCDC converter, and
wherein the second pattern is ground.

19. The electronic device of claim 13, further comprising a power supply configured to supply power to the first pattern and switch to a hiccup mode that periodically turns on and off power based on overcurrent being detected,
wherein the narrow pattern is broken within one cycle of the hiccup mode.

20. The electronic device of claim 13, wherein the MLCC has a capacitance of 10 uF or less.
